(19) United States
(12) Patent Application Publication
(10) Pub. No.: US 2025/0206883 A1
(43) Pub. Date: Jun. 26, 2025

(54) POLYIMIDE PRECURSOR COMPOSITION FOR FLEXIBLE WIRING BOARDS, POLYIMIDE FILM, AND POLYIMIDE METAL LAMINATE

(71) Applicant: UBE Corporation, Ube-Shi (JP)

(72) Inventors: Kosuke YAMAJI, Ube-shi (JP); Nobu IIZUMI, Ube-shi (JP); Hiroto FUKATA, Ube-shi (JP); Keiji IWAMOTO, Ube-shi (JP)

(21) Appl. No.: 18/848,286

(22) PCT Filed: Mar. 29, 2023
(86) PCT No.: PCT/JP2023/012958

§ 371 Date: Sep. 18, 2024

(30) Foreign Application Priority Data
Mar. 29, 2022 (JP) 2022-053306

(51) Int. Cl. C08G 73/10; C08J 5/18

(52) U.S. Cl. CPC C08G 73/1067; C08G 73/1042; C08J 5/18; C08J 2379/08

(57) ABSTRACT

A polyimide precursor composition for flexible wiring boards, which contains a polyimide precursor having a repeating unit represented by general formula (I).

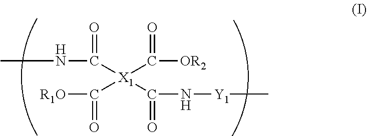

In the formula, 70 mol % to 90 mol % of X₁ is a group represented by following formula (21), and 10 to 30 mol % is a group represented by following formula (22) and/or a group represented by following formula (23),

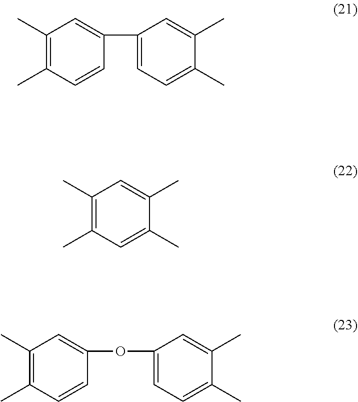

45 mol % to 100 mol % of Y₁ is a group represented by the formula (1):

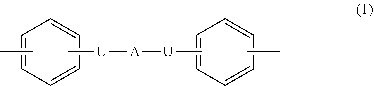

and in formula (1), A is a structure represented by formula (A):

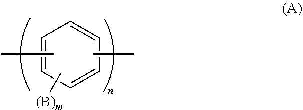

in which n is 1 to 4, m is 0 to 4, B is an alkyl group having 1 to 6 carbon atoms, and U represents —CO—O— or —O—CO—.

### TECHNICAL FIELD

The present invention relates to a polyimide film for flexible wiring boards, more particularly to a polyimide film suitable for circuit boards in high frequency bands, and a polyimide precursor composition for producing the same.

### BACKGROUND ART

Polyimide films have excellent thermal and electrical properties and are therefore widely used in electronic devices such as flexible wiring boards, tapes for TAB (Tape Automated Bonding), and the like. In particular, it is known that polyimides with a low linear expansion coefficient and a high elastic modulus can be obtained by using 3,3′,4,4′-biphenyltetracarboxylic dianhydride and p-phenylenediamine as the tetracarboxylic acid component and the diamine component, respectively.

Meanwhile, in recent years, communication devices such as smartphones have begun to use high-frequency bands near 5 GHz and even 10 GHz or higher. For a polyimide which is a material for flexible circuit boards that transmit high-frequency signals, materials having a small dielectric loss tangent, that is, those having small transmission loss when used as a flexible wiring board are required.

Patent Document 1 (JP 2019-210342 A) proposes a polyimide film with a small dielectric loss tangent, which “contains at least one of p-phenylene bis(trimellitic acid monoester anhydride) and 3,3′,4,4′-biphenyltetracarboxylic dianhydride as an aromatic acid dianhydride component, and at least one of 4,4′-diaminodiphenyl ether, 1,3-bis(4-aminophenoxy)benzene, bis(4-aminophenyl)terephthalate, and 2,2′-bis(trifluoromethyl)benzidine as an aromatic diamine component” (see claim 4).

Patent Document 2 (JP 2021-74894 A) describes a multilayer polyimide film having a thermoplastic polyimide resin layer on at least one side of a non-thermoplastic polyimide resin layer, in which the non-thermoplastic polyimide resin layer is a reaction product of an acid dianhydride and a diamine, and the tetracarboxylic acid dianhydride contains 30 mol % or more of a specific ester-based tetracarboxylic acid dianhydride, and/or the diamine contains 30 mol % or more of a specific ester-based diamine (see claim 1).

Polyimide films using ester-based diamine compounds such as the diamine compounds disclosed in the above-mentioned documents 1 and 2 are also disclosed in Patent Documents 3 to 5.

### CITATION LIST

### Patent Document

Patent Document 1: Japanese Patent Laid-Open No. 2019-210342
Patent Document 2: Japanese Patent Laid-Open No. 2021-74894
Patent Document 3: Japanese Patent Laid-Open No. H11-199668
Patent Document 4: WO 2008/056808
Patent Document 5: Japanese Patent Laid-Open No. 2007-246709

### SUMMARY OF THE INVENTION

### Technical Problem

However, polyimide films for flexible wiring boards are required to have not only a small dielectric loss tangent but also various other properties. For example, in the process of forming wiring from a flexible copper-clad laminate, chemical treatments are performed in many steps such as resist film formation, exposure, development, etching, and resist film removal. In particular, the alkaline solutions, which are used in resist film development and the removal thereof, cause degradation of polyimide films, resulting in a problem of reduced repeated-bending properties.

An object of the present invention is to provide a polyimide precursor composition for flexible wiring boards, which can be used to produce a polyimide film that has a small dielectric loss tangent in the high frequency range and at the same time has excellent alkali resistance and is suitable for producing flexible wiring boards, and a polyimide film.

Another object of the present invention is to provide a polyimide-metal laminate, such as a copper-clad laminate, using as a substrate a polyimide film obtained from the polyimide precursor composition, and a flexible printed wiring board obtained by processing the polyimide-metal laminate.

### Solution to Problem

The main disclosures of the present application are summarized as follows.

1. A polyimide precursor composition for flexible wiring boards, comprising a polyimide precursor having a repeating unit represented by the following general formula (I).

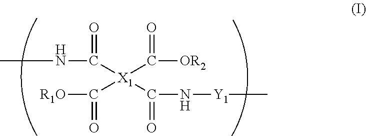

{wherein in general formula I, X₁ is a tetravalent aliphatic group or aromatic group, Y₁ is a divalent aliphatic group or aromatic group, R₁ and R₂ are each independently a hydrogen atom, an alkyl group having 1 to 6 carbon atoms or an alkylsilyl group having 3 to 9 carbon atoms; wherein
70 mol % to 90 mol % of X₁ is a group represented by the following formula (21), and 10 to 30 mol % is a group represented by the following formula (22) and/or a group represented by the following formula (23),

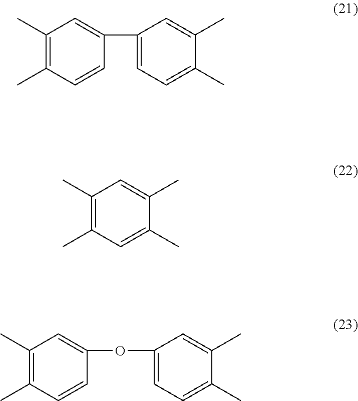

and
45 mol % to 100 mol % of Y₁ is a group represented by the formula (1):

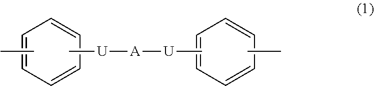

wherein in formula (1), A is a structure represented by formula (A):

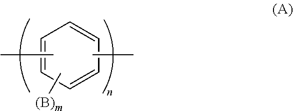

where n is an integer of 1 to 4, m is an integer of 0 to 4, B is one selected from the group consisting of an alkyl group having 1 to 6 carbon atoms, an alkoxy group having 1 to 6 carbon atoms, a halogen group, and a fluoroalkyl group having 1 to 6 carbon atoms, and U independently represents —CO—O— or —O—CO—.}

2. The polyimide precursor composition according to the above item 1, wherein A is a structure selected from the group consisting of a. 1,4-phenylene group and a 4,4′-biphenylene group.

3. A polyimide film for flexible wiring boards, obtained from the polyimide precursor composition according to the above item 1 or 2.

4. A polyimide metal laminate comprising a polyimide film according to the above item 3 and a metal foil or metal layer laminated therewith.

5. A flexible wiring board having wiring formed by patterning the metal foil or metal layer of the polyimide metal laminate according to the above item 4.

### Advantageous Effects of Invention

According to the present invention, provided is a polyimide precursor composition for flexible wiring boards, which can be used to produce a polyimide film that has a small dielectric loss tangent in the high frequency range and at the same time has excellent alkali resistance and is suitable for producing flexible wiring boards, and a polyimide film obtainable from this precursor composition.

Furthermore, according to another aspect of the present invention, provided is a polyimide-metal laminate, such as a copper-clad laminate, using as a substrate a polyimide film obtained from the polyimide precursor composition, and a flexible printed wiring board obtained by processing the polyimide-metal laminate.

### DESCRIPTION OF EMBODIMENTS

### «Polyimide Precursor Composition»

The polyimide precursor composition for flexible wiring boards comprises a polyimide precursor having a repeating unit represented by general formula (I), and in a form when it is distributed, comprises a solvent, and the polyimide precursor is dissolved in the solvent.

The polyimide precursor includes a repeating unit represented by the following general formula (I):

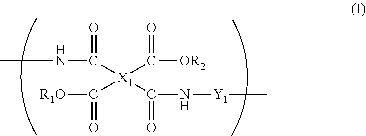

(wherein in general formula I, X₁ is a tetravalent aliphatic group or aromatic group, Y₁ is a divalent aliphatic group or aromatic group, R₁ and R₂ are each independently a hydrogen atom, an alkyl group having 1 to 6 carbon atoms or an alkylsilyl group having 3 to 9 carbon atoms.).
Particularly preferred are poly amic acids in which R₁ and R₂ are hydrogen atoms.

The polyimide precursor will be explained in terms of monomers (tetracarboxylic acid component, diamine component, and other components) that provide X₁ and Y₁ in the general formula (I), and then the production method will be explained.

In the present specification, the tetracarboxylic acid component includes tetracarboxylic acid, tetracarboxylic dianhydride, and other tetracarboxylic acid derivatives such as tetracarboxylic acid silyl ester, tetracarboxylic acid ester and tetracarboxylic acid chloride, each of which is used as a starting material for producing a polyimide. Although not particularly limited, it is convenient to use tetracarboxylic acid dianhydride from the view point of production, and the following description will be made to examples using tetracarboxylic acid dianhydride as a tetracarboxylic acid component. Further, the diamine component is a diamine compound having two amino groups (—NH₂), which is used as a starting material for producing a polyimide.

### <X₁ and Tetracarboxylic Acid Component>

X₁ may be either an aliphatic group or an aromatic group, but is preferably an aromatic group. Preferably 50 mol % or more, more preferably 70 mol % or more, and even more preferably 90 mol % or more (100 mol % is also highly preferred) of X₁ is an aromatic group.

Examples of the aromatic group X₁ include the following structures.

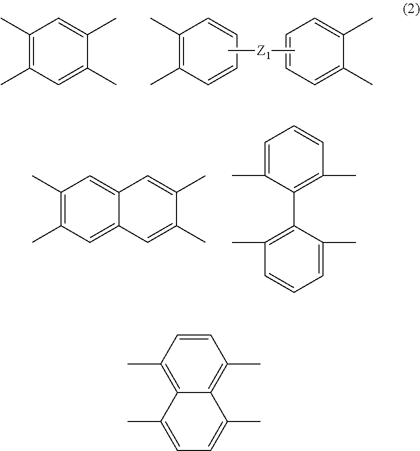

(wherein Z₁ is a direct bond, or any one of the following divalent groups:

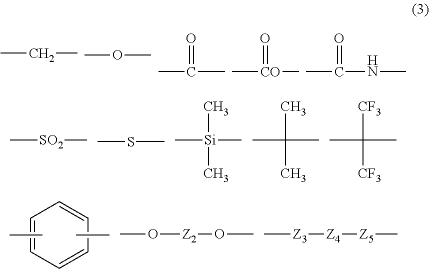

wherein Z₂ in the formula is a divalent organic group, Z₃ and Z₄ are each independently an amide bond, an ester bond or a carbonyl bond, and Z is an organic group containing an aromatic ring.)

Specific examples of Z₂ include an aliphatic hydrocarbon group having 2 to 24 carbon atoms, and an aromatic hydrocarbon group having 6 to 24 carbon atoms.

Specific examples of Z includes an aromatic hydrocarbon group having 6 to 24 carbon atoms.

In the present invention, 70 mol % to 90 mol % of X₁ is a group represented by the following formula (21), and 10 to 30 mol % is a group represented by the following formula (22) and/or a group represented by the following formula (23).

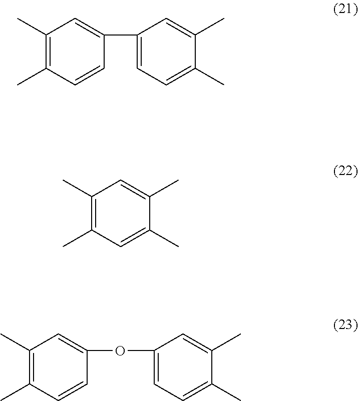

When the groups represented by formulas (21) to (23) are within the above ranges in X₁, the resulting polyimide film has excellent alkali resistance. When the group represented by formula (21) is present in an amount of 70 mol % or more in X₁, the resulting polyimide can have a reduced dielectric loss tangent and a low linear thermal expansion coefficient. On the other hand, when the group represented by formula (22) and/or the group represented by formula (23) are present, particularly when they are present in an amount of 10 mol % or more, the dielectric loss tangent and storage modulus at 350° C. are improved (decreased) compared to when these groups are not present, and therefore, these cases are preferable.

As long as the groups represented by formula (21), formula (22) and formula (23) satisfy the above range, other groups derived from other tetracarboxylic dianhydrides may be contained. The groups derived from other tetracarboxylic dianhydrides may be either aromatic groups or aliphatic groups (preferably alicyclic groups), but are preferably aromatic groups. It is also preferred that X₁ consists only of groups represented by formula (21), formula (22) and/or formula (23).

Among tetracarboxylic acid components that provide a repeating unit of the general formula (I) in which X₁ is a tetravalent group having an aromatic ring, those giving the groups of formulae (21), (22), and (23) are 3,3′,4,4-biphenyltetracarboxylic dianhydride, pyromellitic dianhydride, and 4,4-oxydiphthalic dianhydride. Other tetracarboxylic acid components include halogen-unsubstituted aromatic tetracarboxylic dianhydrides such as 2,3,3′,4′-biphenyltetracarboxylic dianhydride, 2,2′,3,3′-biphenyltetracarboxylic dianhydride, benzophenonetetracarboxylic dianhydride, diphenylsulfonetetracarboxylic dianhydride, p-terphenyltetracarboxylic dianhydride, m-terphenyltetracarboxylic dianhydride, and 1,4-phenylenebis(1,3-dioxo-1,3-dihydroisobenzofuran-5-carboxylate); and halogen-substituted tetracarboxylic acid dianhydrides such as 4,4′-(hexafluoroisopropylidene)diphthalic anhydride, 3,3-(hexafluoroisopropylidene)diphthalic anhydride, 5,5′-[2,2,2-trifluoro-1-[3-(trifluoromethyl)phenyl]ethylidene]diphthalic anhydride, 5,5′-[2,2,3,3,3-pentafluoro-1-(trifluoromethyl)propylidene]diphthalic anhydride, 1H-difuro[3,4-b:3′,4′-i]xanthene-1,3,7,9(11H)-tetrone, 5,5′-oxybis[4,6,7-trifluoro-pyromellitic anhydride], 3,6-bis(trifluoromethyl)pyromellitic dianhydride, 4-(trifluoromethyl)pyromellitic dianhydride, 1,4-difluoropyromellitic dianhydride, 1,4-bis(3,4-dicarboxytrifluorophenoxy)tetrafluorobenzene dianhydride; and the like. These may be used alone or in combination of a plurality of types.

The aliphatic group X₁ may be either an open-chain aliphatic group or an alicyclic group, but is preferably an alicyclic group. As X₁ that is an alicyclic group, preferred is a tetravalent group having an alicyclic structure having 4 to 40 carbon atoms, and more preferred are those having at least one aliphatic 4- to 12-membered ring, more preferably an aliphatic 4-membered ring or an aliphatic 6-membered ring. Preferred examples of the tetravalent group having an aliphatic 4-membered ring or an aliphatic 6-membered ring include the following groups.

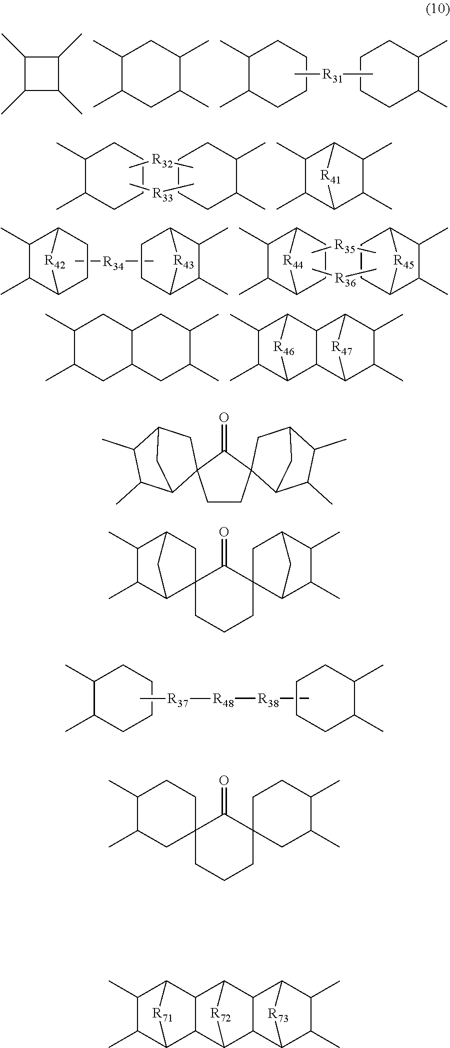

(wherein R₃₁ to R₃₈ are each independently a direct bond, or a divalent organic group; and R₄₁ to R₄₇ and R₇₁ to R₇₃ are each independently represent one selected from the group consisting of groups represented by the formulas. —CH₂—, —CH═CH—, —CH₂CH₂—, —O— and —S—. R₄₈ is an organic group having an aromatic ring or an alicyclic structure.)

Specific examples of R₃₁, R₃₂, R₃₃, R₃₄, R₃₅, R₃₆, R₃₇ and R₃₈ include a direct bond, or an aliphatic hydrocarbon group having 1 to 6 carbon atoms, or an oxygen atom (—O—), a sulfur atom (—S—), a carbonyl bond, an ester bond, and an amide bond.

Examples of the organic group having an aromatic ring as R₄₈ include the following groups.

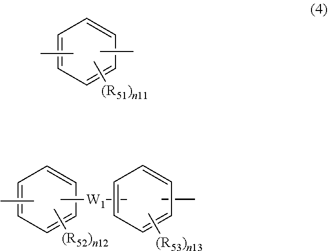

(wherein W₁ is a direct bond, or a divalent organic group; n₁₁ to n₁₃ each independently represent an integer of 0 to 4; and R₅₁, R₅₂ and R₅₃ are each independently an alkyl group having 1 to 6 carbon atoms, a halogen group, a hydroxyl group, a carboxyl group, or a trifluoromethyl group.)

Specific examples of W₁ include divalent groups represented by the formula (5) as described below, and divalent groups represented by the formula (6) as described below.

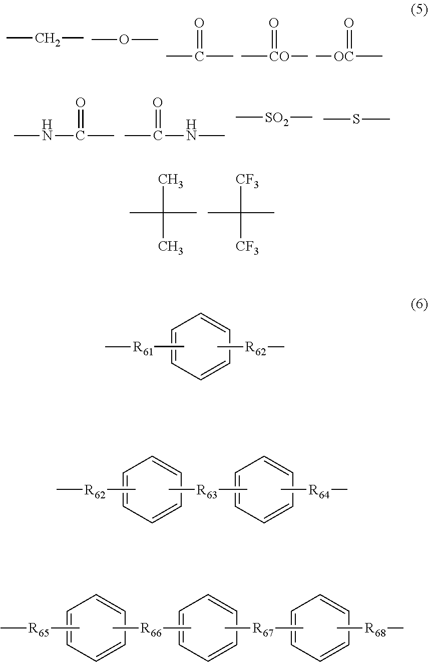

(wherein R₆₁ to R₆₈ in the formula (6) each independently represent any one of the divalent groups represented by the formula (5).)

Among them, the following groups are particularly preferred as the tetravalent group having an alicyclic structure.

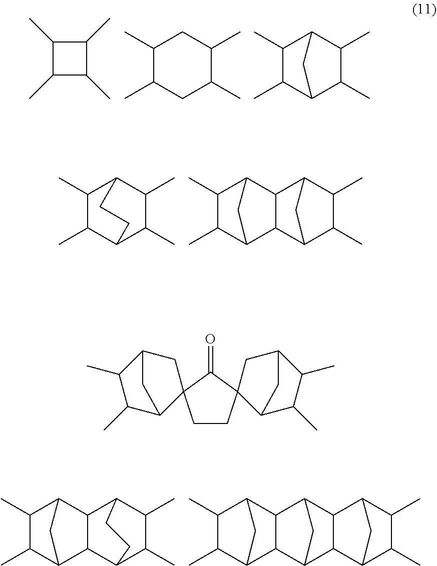

The tetracarboxylic acid components giving the alicyclic group X₁ include, for example, 1,2,3,4-cyclobutane tetracarboxylic dianhydride, cyclohexane-1,2,4,5-tetracarboxylic dianhydride, [1,1′-bi(cyclohexane)]-3,34,4′-tetracarboxylic dianhydride, [1,1′-bi(cyclohexane)]-2,3,3′,4′-tetracarboxylic dianhydride, [1,1′-bi(cyclohexane)]-2.2′,3,3′-tetracarboxylic dianhydride, 4,4′-methylenebis(cyclohexane-1,2-dicarboxylic anhydride), 4,4′-(propane-2,2-diyl)bis(cyclohexane-1,2-dicarboxylic anhydride), 4,4′-oxybis(cyclohexane-1,2-dicarboxylic anhydride), 4,4′-thiobis(cyclohexane-1,2-dicarboxylic anhydride), 4,4′-sulfonylbis(cyclohexane-1,2-dicarboxylic anhydride), 4,4′-(dimethylsilanediyl)bis(cyclohexane-1,2-dicarboxylic anhydride), 4,4′-(tetrafluoropropane-2,2-diyl)bis(cy clohexane-1,2-dicarboxylic anhydride), octahydropentalene-1,3,4,6-tetracarboxylic dianhydride, bicyclo[2.2.1]heptane-2,3,5,6-tetracarboxylic dianhydride, 6-(carboxymethyl)bicyclo[2.2.1]heptane-2,3,5-tricarboxylic dianhydride, bicyclo[2.2.2]octane-2,3,5,6-tetracarboxylic dianhydride, bicyclo[2.2.2]oct-5-ene-2,3,7,8-tetracarboxylic dianhydride, tricyclo[4.2.2.02,5]decane-3,4,7,8-tetracarboxylic dianhydride, tricyclo[4.2.2.02,5]dec-7-ene-3,4,9,10-tetracarboxylic dianhydride, 9-oxatricyclo[4.2.1.02,5]nonane-3,4,7,8-tetracarboxylic dianhydride, norbornane-2-spiro-β-cyclopentanone-α′-spiro-2″-norbornane-5,5″,6,6″-tetracarboxylic dianhydride, (4arH,8acH)-decahydro-1t,4t:5c,8c-dimethanonaphthalene-2c,3c,6c,7c-tetracarboxylic dianhydride, (4arH,8acH)-decahydro-1t,4t:5c,8c-dimethanonaphthalene-2t,3t,6c,7c-tetracarboxylic dianhydride, decahydro-1,4-ethano-5,8-methanonaphthalene-2,3,6,7-tetracarboxylic dianhydride, tetradecahydro-1,4:5,8:9,10-trimethanoanthracene-2,3,6,7-tetracarboxylic dianhydride; and the like. These may be used alone or in combination of a plurality of types.

The tetracarboxylic acid components giving the open-chain aliphatic group X₁ include straight chain or branched tetracarboxylic acid dianhydrides having about 4 to 10 carbon atoms, such as 1,2,3,4-butanetetracarboxylic dianhydride and 1,2,3,4-pentanetetracarboxylic dianhydride.

Y₁ comprises at least a group represented by the formula (1):

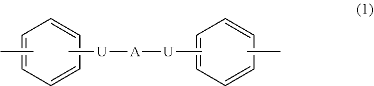

A includes a group represented by formula (A):

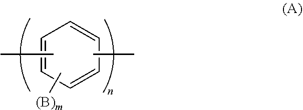

(wherein n is an integer of 1 to 4, n is an integer of 0 to 4, B is one selected from the group consisting of an alkyl group having 1 to 6 carbon atoms, an alkoxy group having 1 to 6 carbon atoms, a halogen group, and a fluoroalkyl group having 1 to 6 carbon atoms.).
n is preferably 1 to 3, more preferably 1 or 2. m is preferably 0 or 1.
Examples of A include 1,4-phenylene, 1,3-phenylene, 4,4′-biphenylene, 3,4′-biphenylene, 3,3-biphenylene, and 4,4″-p-terphenylene. In particular, 1,4-phenylene, 4,4′-biphenylene, and 4,4″-p-terphenylene bonded at the para position are preferred.

Preferably, one of U represents —CO—O— and the other represents —O—CO—. That is, a preferred structure of formula (1) is represented by formula (1-1) or formula (1-2).

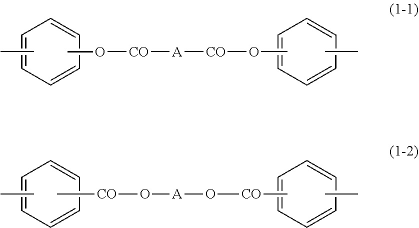

The positional relationship between U and the bond in formula (1) (the relationship between U and N in formula (1)) may be any of the ortho, meta or para positions, but is preferably the para position.

Examples of diamine compounds which provide the group of formula (1) include bis(4-aminophenyl)terephthalate (abbreviated as BPTP), bis(4-aminophenyl)biphenyl-4,4′-dicarboxylate (abbreviated as APBP), and [4-(4-aminobenzoyl)oxyphenyl]4-aminobenzoate (abbreviated as ABHQ).

The proportion of the group of formula (1) in Y₁ is 45 mol % to 100 mol %, preferably 45 mol % to 80 mol %, even more preferably 45 mol % to 60 mol %, and even more preferably 45 mol % to 55 mol %. These ranges are preferable because the obtained polyimide film has a low dielectric loss tangent and excellent alkali resistance.

Y₁ other than formula (1) may be either an aliphatic group or an aromatic group, but an aromatic group is preferred.

Examples of the aromatic group Y₁ include the following structures.

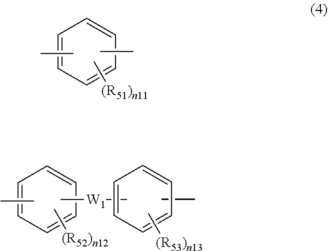

(wherein W₁ is a direct bond, or a divalent organic group; n₁₁ to n₁₃ each independently represent an integer of 0 to 4; and R₅₁, R₅₂ and R₅₃ are each independently an alkyl group having 1 to 6 carbon atoms, a halogen group a hydroxyl group, a carboxyl group, or a trifluoromethyl group.)

Specific examples of W₁ include divalent groups represented by the formula (5) as described below, and divalent groups represented by the formula (6) as described below.

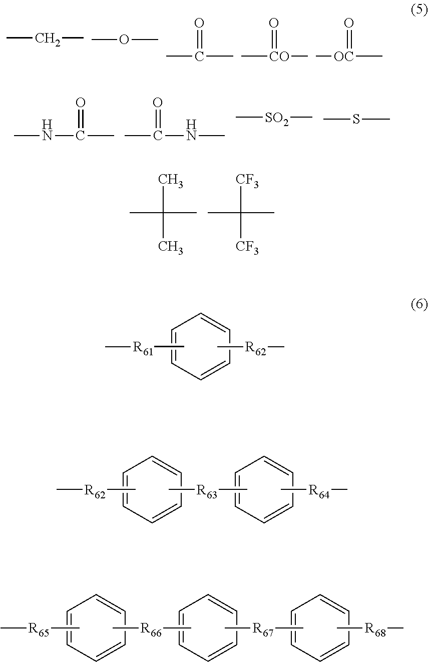

(wherein R₆₁ to R₆₈ in the formula (6) each independently represent any one of the divalent groups represented by the formula (5).)

The diamine components giving a divalent group Y₁ having an aromatic ring include, for example, p-phenylenediamine, m-phenylenediamine, 2,4-toluenediamine, 3,3′-dihydroxy-4,4′-diaminobiphenyl, bis(4-amino-3-carboxyphenyl)methane, benzidine, 3,3′-diamino-biphenyl, 2,2′-bis(trifluoromethyl)benzidine, 3,3′-bis(trifluoromethyl) benzidine, m-tolidine, 4,4′-diaminobenzanilide, 3,4′-diaminobenzanilide, N,N′-bis(4-aminophenyl)terephthalamide, N,N′-p-phenylenebis(p-amino benzamide), 4-aminophenoxy-4-diaminobenzoate, bis(4-aminophenyl) terephthalate, biphenyl-4,4′-dicarboxylic acid bis(4-aminophenyl)ester, p-phenylenebis(p-aminobenzoate), bis(4-aminophenyl)-[1,1′-biphenyl]-4,4′-dicarboxylate, [1,1′-biphenyl]-4,4′-diyl bis(4-aminobenzoate), 4,4′-oxydianiline (also known as 4,4′-diaminodiphenyl ether), 3,4′-oxydianiline, 3,3′-oxydianiline, p-methylenebis(phenylenediamine), 1,3-bis(4-aminophenoxy)benzene, 1,3-bis(3-aminophenoxy)benzene, 1,4-bis(4-aminophenoxy)benzene, 4,4′-bis(4-aminophenoxy)biphenyl, 4,4′-bis(3-amino phenoxy)biphenyl, 2,2-bis(4-(4-aminophenoxy)phenyl)hexafluoropropane, 2,2-bis(4-aminophenyl)propane, bis(4-aminophenyl)sulfone, 2,2-bis(4-aminophenyl)hexafluoropropane, bis(4-aminophenyl)sulfone, 3,3-bis(trifluoromethyl)benzidine, 3,3′-bis((aminophenoxy)phenyl)propane, 2,2′-bis(3-amino-4-hydroxyphenyl)hexafluoropropane, bis(4-(4-aminophenoxy) diphenyl)sulfone, bis(4-(3-aminophenoxy)diphenyl)sulfone, octafluorobenzidine, 3,3′-dimethoxy-4,4′-diaminobiphenyl, 3,3′-dichloro-4,4′-diaminobiphenyl, 3,3′-difluoro-4,4′-diaminobiphenyl, 2,4-bis(4-aminoanilino)-6-amino-1,3,5-triazine, 2,4-bis(4-aminoanilino)-6-methylamino-1,3,5-triazine, 2,4-bis(4-aminoanilino)-6-ethylamino-1,3,5-triazine, and 2,4-bis(4-amino anilino)-6-anilino-1,3,5-triazine. Examples of the diamine component giving a repeating unit of the general formula (1) in which Y₁ is a divalent group having a fluorine atom-containing aromatic ring include 2,2′-bis(trifluoromethyl)benzidine, 3,3′-bis(trifluoromethyl)benzidine, 2,2-bis[4-(4-aminophenoxy)phenyl]hexafluoropropane, 2,2-bis(4-aminophenyl) hexafluoropropane, and 2,2′-bis(3-amino-4-hydroxyphenyl)hexafluoropropane. In addition, preferred diamine compounds include 9,9-bis(4-aminophenyl)fluorene, 4,4′-(((9H-fluorene-9,9-diyl)bis([1,1′-biphenyl]-,2-diyl))bis(oxy))diamine, [1,1′4′, “-terphenyl]-4,4”-diamine, 4,4′-([1,1-binaphthalene]-2,2′-diylbis(oxy))diamine. The diamine component may be used alone or in combination of a plurality of types.

Examples of the group Y₁ having an alicyclic structure include the following structures.

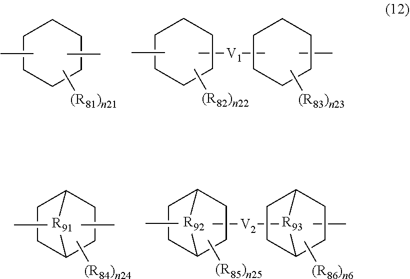

(wherein V₁ and V₂ are each independently a direct bond, or a divalent organic group; n₂₁ to n₂₆ each independently represent an integer of 0 to 4; R₈₁ to R₈₆ are each independently an alkyl group having 1 to 6 carbon atoms, a halogen group, a hydroxyl group, a carboxyl group, or a trifluoromethyl group; and R₉₃, R₉₂ and R₉₃ are each independently one selected from the group consisting of groups represented by the formulas: —CH₂—, —CH═CH—, —CH₂CH₂—, —O— and —S—)

Specific examples of V₁ and V₂ include a direct bond and divalent groups represented by the formula (5) as described above.

The diamine components giving Y₁ having an alicyclic structure include, for example, 1,4-diaminocyclohexane. 1,4-diamino-2-methylcyclohexane, 1,4-diamino-2-ethylcyclohexane, 1,4-diamino-2-n-propylcyclohexane, 1,4-diamino-2-isopropylcyclohexane, 1,4-diamino-2-n-butylcyclohexane, 1,4-diamino-2-isobutylcyclohexane, 1,4-diamino-2-sec-butylcyclohexane, 1,4-diamino-2-tert-butylcyclohexane, 1,2-diaminocyclohexane, 1,3-diaminocyclobutane, 1,4-bis(aminomethyl)cyclohexane, 1,3-bis(aminomethyl)cyclohexane, diaminobicycloheptane, diaminomethylbicycloheptane, diaminooxybicycloheptane, diaminomethyloxybicycloheptane, isophoronediamine, diaminotricyclodecane, diaminomethyltricyclodecane, bis(aminocyclohexyl)methane, bis(aminocyclohexyl)isopropylidene, 6,6′-bis(3-aminophenoxy)-33,3,3′-tetramethyl-1,1′-spirobiindane, and 6,6′-bis(4-aminophenoxy)-3.3.3′,3′-tetramethyl-11′-spirobiindane. The diamine component may be used alone or in combination of a plurality of types.

Y₁ other than formula (1) is preferably an aromatic group. When described in terms of diamine compounds, examples thereof include p-phenylenediamine, 4,4″-diamino-p-terphenyl, 2,2′-dimethyl-4,4′-diaminobiphenyl, 4,4′-bis(4-aminophenoxy)biphenyl, and 1,3-bis(4-aminophenoxy)benzene.

In particular, when formula (1) is less than 100 mol %, the proportion of p-phenylenediamine and/or 4,4′-diamino-p-terphenyl in Y₁ other than formula (1) is preferably 60 mol % or more, more preferably 70 mol % or more, even more preferably 80 mol % or more, and even more preferably 100 mol %. In other words, it is also highly preferable that Y₁ consists of a group of formula (1) and a group derived from p-phenylenediamine and/or 4,4″-diamino-p-terphenyl.

The polyimide precursor composition for flexible wiring boards is obtained by reacting a tetracarboxylic acid component with a diamine component in a solvent. Using approximately equimolar amounts of a tetracarboxylic acid component (tetracarboxylic dianhydride) and a diamine component, this reaction is carried out at a relatively low temperature, for example, 100° C. or lower, preferably 80° C. or lower. Although not limited thereto, the reaction temperature is usually 25′C to 100° C., preferably 25° C. to 80′C, and more preferably 30° C. to 80° C., and the reaction time is, for example, about 0.1 to 72 hours, and preferably about 2 to 60 hours. The reaction can be carried out in an air atmosphere, but is usually suitably carried out in an inert gas atmosphere, preferably a nitrogen gas atmosphere.

Here, the approximately equimolar amount of the tetracarboxylic acid component (tetracarboxylic dianhydride) and the diamine component specifically means a molar ratio[tetracarboxylic acid component/diamine component] of about 0.90 to 1.10, preferably about 0.95 to 1.05.

The solvent used in preparing the polyimide precursor composition includes preferably water or an aprotic solvent such as N,N-dimethylformamide, N,N-dimethylacetamide, N-methyl-2-pyrrolidone, N-ethvl-2-pyrrolidone, 1,3-dimethyl-2-imidazolidinone, or dimethyl sulfoxide, and is not particularly limited to its structure because any type of solvent can be used without problems as long as it dissolves the starting material monomer components and the resulting polyimide precursor. As the solvent, water, amide solvents such as N,N-dimethylformamide, N,N-dimethylacetamide, N-methylpyrrolidone, and N-ethyl-2-pyrrolidone; cyclic ester solvents such as γ-butyrolactone, γ-valerolactone, δ-valerolactone, γ-caprolactone, ε-caprolactone, and α-methyl-γ-butyrolactone; carbonate solvents such as ethylene carbonate and propylene carbonate; glycol solvents such as triethylene glycol, phenol solvents such as m-cresol, p-cresol, 3-chlorophenol, and 4-chlorophenol; acetophenone, 1,3-dimethyl-2-imidazolidinone, sulfolane, dimethyl sulfoxide and the like are preferably used. Furthermore, other common organic solvents can be used, such as phenol, o-cresol, butyl acetate, ethyl acetate, isobutyl acetate, propylene glycol methyl acetate, ethyl cellosolve, butyl cellosolve, 2-methyl cellosolve acetate, ethyl cellosolve acetate, butyl cellosolve acetate, tetrahydrofuran, dimethoxyethane, diethoxyethane, dibutyl ether, diethylene glycol dimethyl ether, methyl isobutyl ketone, diisobutyl ketone, cyclopentanone, cyclohexanone, methyl ethyl ketone, acetone, butanol, ethanol, xylene, toluene, chlorobenzene, turpentine, mineral spirits, petroleum naphtha solvents, and the like. The solvents may be used in combination of two or more types.

In the production of the polyimide precursor composition, although there are no particular limitations, the monomers and the solvent are charged at a concentration such that the solids concentration of the polyimide precursor (polyimide equivalent mass concentration) is, for example, 5 to 45 mass % and the reaction is carried out.

The solution viscosity of the polyimide precursor composition may be appropriately selected depending on the purpose of use (coating, casting, and the like) and the purpose of production. For example, it is preferable that the polyamic acid (polyimide precursor) solution has a rotational viscosity measured at 30° C. of about 0.1 to 5000 poise, particularly 0.5 to 2000 poise, and further preferably about 1 to 2000 poise, from the viewpoint of workability in handling the polyamic acid solution.

As the polyimide precursor composition, a reaction solution of a tetracarboxylic acid component and a diamine component may be used as it is, or may be concentrated or diluted by adding a solvent if necessary. Therefore, the solvent contained in the polyimide precursor composition may be the solvent used in the reaction of the tetracarboxylic acid component and the diamine component. The solvent added if necessary may be the same as or different from the reaction solvent.

The polyimide precursor composition may comprise an imidization catalyst, an organic phosphorus-containing compound, inorganic fine particles, and the like, if necessary, in the case of thermal imidization. The polyamic acid solution may comprise a cyclization catalyst, a dehydrating agent, inorganic fine particles, and the like, if necessary, in the case of chemical imidization.

The imidization catalyst may be a substituted or unsubstituted nitrogen-containing heterocyclic compound, an N-oxide compound of the nitrogen-containing heterocyclic compound, a substituted or unsubstituted amino acid compound, an aromatic hydrocarbon compound having a hydroxyl group, or an aromatic heterocyclic compound. Examples include especially lower alkyl group-substituted or aromatic group-substituted imidazoles, such as 1,2-dimethylimidazole, N-methylimidazole, N-benzyl-2-methylimidazole, 2-methylimidazole, 2-ethyl-4-methylimidazole, and 2-phenylimidazole; benzimidazoles such as 5-methylbenzimidazole; substituted pyridines such as isoquinoline, 3,5-dimethylpyridine, 3,4-dimethylpyridine, 2,5-dimethylpyridine, 2,4-dimethylpyridine, 4-n-propylpyridine; and the like. The amount of the imidization catalyst used is preferably about 0.01 to 2 times the equivalent, particularly about 0.02 to 1 times the equivalent, based on the amide acid unit of the polyamide acid. The use of an imidization catalyst can improve the physical properties of the resulting polyimide film, particularly the elongation and edge tear resistance.

Examples of organic phosphorus-containing compounds include phosphoric acid esters such as monocaproyl phosphate, monooctyl phosphate, monolauryl phosphate, monomyristyl phosphate, monocetyl phosphate, monostearyl phosphate, phosphoric acid monoester of triethylene glycol monotridecyl ether, phosphoric acid monoester of tetraethylene glycol monolauryl ether, phosphate monoester of diethylene glycol monostearyl ether, dicaproyl phosphate, dioctyl phosphate, dicapryl phosphate, dilauryl phosphate, dimyristyl phosphate, dicetyl phosphate, distearyl phosphate, phosphoric diester of tetraethylene glycol mononeopentyl ether, phosphoric diester of triethylene glycol monotridecyl ether, hosphoric diester of tetraethylene glycol monolauryl ether, and phosphoric diester of diethylene glycol monostearyl ether, and phosphoric triester, for example, trimethyl phosphate and triphenyl phosphate, and amine salts of these phosphoric acid esters. The amines include ammonia, monomethylamine, monoethylamine, monopropylamine, monobutylamine, dimethylamine, diethylamine, dipropylamine, dibutylamine, trimethylamine, triethylamine, tripropylamine, tributylamine, monoethanolamine, diethanolamine, triethanolamine, and the like.

Examples of cyclization catalysts include aliphatic tertiary amines such as trimethylamine and triethylenediamine, aromatic tertiary amines such as dimethylaniline, and heterocyclic tertiary amines such as isoquinoline, pyridine, α-picoline, and β-picoline.

Examples of the dehydrating agent include aliphatic carboxylic anhydrides such as acetic anhydride, propionic anhydride, and butyric anhydride, and aromatic carboxylic acid anhydrides such as benzoic anhydride.

Examples of inorganic fine particles include inorganic oxide powders in a form of particle such as titanium dioxide powder, silicon dioxide (silica) powder, magnesium oxide powder, aluminum oxide (alumina) powder, and zinc oxide powder; inorganic nitride powders in a form of particle such as silicon nitride powder, and titanium nitride powder; inorganic carbide powders such as silicon carbide powders, and inorganic salt powders in a form of particle such as calcium carbonate powders, calcium sulfate powders, and barium sulfate powders. Two or more types of these inorganic fine particles may be used in combination. In order to uniformly disperse these inorganic fine particles, any means that are publicly known per se can be used.

### «Method for Manufacturing Polyimide Film»

The polyimide precursor compositions of the present invention can be used to prepare single or multilayer polyimide films.

The polyimide film can be produced by a known method. For example, the following methods (1) and (2) can be used to produce a single-layer polyimide film.
(1) A method comprising casting or applying a polyimide precursor composition onto a support, and then heating in that state on the support to complete imidization to obtain a polyimide film.
(2) A method comprising casting or applying a polyimide precursor composition onto a support, heating to produce a self-supporting film (gel film) in a semi-cured state or an earlier dry state, peeling off the self-supporting film from the support, and heating the self-supporting film while holding the edges with a tenter device or the like to remove the solvent to proceed with imidization to obtain a polyimide film.

The above method (2) is suitable for continuously producing a long polyimide film.

The single layer polyimide film produced using the polyimide precursor composition of the present invention has excellent alkali resistance and high bending resistance even after immersion in an alkaline solution. The number of folding endurance times until a film breaks according to the MIT folding endurance test described below, when the polyimide film has a thickness of 38 μm or more, is preferably 2500 times or more, more preferably 3000 times or more, even more preferably 5000 times or more, and even more preferably 7000 times or more after immersion in an alkaline solution.

Furthermore, the dielectric loss tangent is preferably less than 0, 0055, more preferably 0.0053 or less, even more preferably 0.0051 or less, even more preferably 0.0044 or less, even more preferably 0.0040 or less, and even more preferably 0.0036 or less at a frequency of 10 GHz and a humidity of 60% RH.

The coefficient of linear thermal expansion (CTE) of the single layer polyimide film of the present invention is preferably 20 ppm/K or less, more preferably 16 ppm/K or less, and even more preferably 13 ppm/K or less. In addition, when used as a heat-resistant PI layer for lamination with a metal foil as described later, it is preferable that the storage modulus at 35° C. is large and the storage modulus at 350° C. is small. The storage modulus at 35° C. is preferably 5.5 GPa or more, more preferably 6 GPa or more, and even more preferably 7 GPa or more, and the storage modulus at 350° C. is preferably 1.4 GPa or less, more preferably 1.35 GPa or less, even more preferably 1.0 GPa or less, and even more preferably 0.8 GPa or less. The lower limit of the storage modulus at 350° C. is not particularly limited, but as an example, it is 0.01 GPa or more.

Examples of methods for producing a multi-layer polyimide film include the following methods (3) and (4).
(3) A method comprising casting or applying a polyimide precursor composition onto a support, producing a self-supporting film, casting or applying a polyimide precursor composition for a second or more layers onto one or both sides of the self-supporting film, and then heating (if necessary, a self-supporting film is produced once, and then the self-supporting film is held by a tenter apparatus,) to complete imidization to obtain a polyimide film.
(4) A method comprising simultaneously casting or applying two or more layers of polyimide precursor compositions onto a support by, for example, a coextrusion method, and then heating (if necessary, a self-supporting film is produced once, and then the self-supporting film is held by a tenter apparatus,) to complete imidization to obtain a polyimide film.

The multilayer polyimide film (or polyimide layer) of the present invention has excellent alkali resistance and is highly resistant to folding even after immersion in an alkaline solution. When the polyimide film has a thickness of 38 μm or more, the number of folding endurance times until breakage in the MIT folding endurance test described later is preferably 2600 times or more, more preferably 3000 times or more after immersion in an alkaline solution.

Furthermore, the dielectric loss tangent is preferably less than 0.0055, more preferably 0.0053 or less, even more preferably 0.0051 or less, even more preferably 0.0044 or less, and even more preferably 0.0040 or less at a frequency of 10 GHz and a humidity of 60% RH.

When the multilayer polyimide film of the present invention is used as a heat-resistant PI layer for lamination with a metal foil as described later, it is preferable that the storage modulus at 35° C. is large and the storage modulus at 350° C. is small. The storage modulus at 35° C. is preferably 4.8 GPa or more, more preferably 5.0 GPa or more, and even more preferably 5.2 GPa or more, and the storage modulus at 350° C. is preferably 1.4 GPa or less, more preferably 1.35 GPa or less, even more preferably 1.0 GPa or less, and even more preferably 0.8 GPa or less. The lower limit of the storage modulus at 350° C. is not particularly limited, but as an example, it is 0.01 GPa or more.

Examples of the form of the multilayer polyimide film include a two-layer structure of fusion-bondable PI layer/heat-resistant PI layer, and a three-layer structure of fusion-bondable PI layer/heat-resistant PI layer/fusion-bondable PI layer (PI is an abbreviation for polyimide). The polyimide precursor composition of the present invention is suitably used as the heat-resistant polyimide layer of the multilayer polyimide film.

### «Fusion-Bondable Polyimide Layer (Fusion-Bondable PI Layer)»

The fusion-bondable polyimide layer in the multi-layer polyimide film is formed from a fusion-bondable polyimide obtained from a tetracarboxylic acid component and a diamine component.

The fusion-bondable polyimide is preferably prepared using, as the tetracarboxylic acid component, at least one tetracarboxylic acid dianhydride selected from 3,3′,4,4′-biphenyltetracarboxylic dianhydride, 2,3,3′,4′-biphenyltetracarboxylic dianhydride (these two components are also collectively referred to as “biphenyltetracarboxylic dianhydride”) and pyromellitic dianhydride in an amount of 50 to 100 mol % based on the total tetracarboxylic acid components. The total amount of these tetracarboxylic acid components is preferably 70 mol % or more, more preferably 80 mol % or more, and even more preferably 90 mol % or more based on the total tetracarboxylic acid components.

When pyromellitic dianhydride is the main component of the tetracarboxylic acid component, the amount of pyromellitic dianhydride is preferably 50 mol % or more and 90 mol % or less, more preferably 65 mol % or more, even more preferably 70 mol % or more, and more preferably 85 mol % or less, and even more preferably 80 mol % or less. The amount of biphenyltetracarboxylic dianhydride is preferably 10 mol % or more and 50 mol % or less, more preferably 15 mol % or more, even more preferably 20 mol % or more, and more preferably 35 mol % or less, and even more preferably 30 mol % or less.

When biphenyltetracarboxylic dianhydride is the main component of the tetracarboxylic acid component, the amount of biphenyltetracarboxylic dianhydride is preferably 50 mol % or more and 100 mol % or less, more preferably 70 mol % or more, and even more preferably 90 mol % or more. The amount of pyromellitic dianhydride is preferably 0 mol % or more and 50 mol % or less, more preferably 30 mol % or less, and even more preferably 10 mol % or less.

When biphenyltetracarboxylic dianhydride is taken as 100 mol %, the ratio of 3,3′,4,4-biphenyltetracarboxylic dianhydride is preferably 50 mol % or more and 100 mol % or less, more preferably 70 mol % or more and more preferably 90 mol % or less, and the ratio of 2,3,3′,4′-biphenyltetracarboxylic dianhydride is preferably 0 mol % or more and 50 mol % or less, more preferably 10 mol % or more and more preferably 30 mol % or less.

As the tetracarboxylic acid component, the above three tetracarboxylic acid components may be used in combination with other tetracarboxylic acid components. Examples of the other tetracarboxylic acid components to be used in combination include 3,3′,4,4′-benzophenonetetracarboxylic dianhydride, bis(3,4-dicarboxyphenyl)ether dianhydride, bis(3,4-dicarboxyphenyl)sulfide dianhydride, bis(3,4-dicarboxyphenyl)sulfone dianhydride, bis(3,4-dicarboxyphenyl)methane dianhydride, 2,2-bis(3,4-dicarboxyphenyl)propane dianhydride, and 1,4-hydroquinone dibenzoate-3,3′,4,4′-tetracarboxylic dianhydride. The tetracarboxylic acid components to be used in combination may be used alone or in combination of two or more.

The fusion-bondable polyimide is preferably prepared using, as a diamine component, a diamine represented by the following chemical formula (13) in an amount of 50 to 100 mol % of the total diamine components. The total amount of these diamine components is preferably 70 mol % or more, more preferably 80 mol % or more, and even more preferably 90 mol % or more of the total diamine components

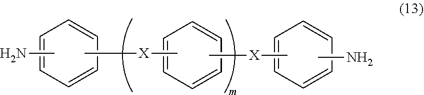

[In formula (13), X represents O, CO, COO, OCO, C(CH₃)₂, CH₂, SO₂, S, or a direct bond, and may have two or more types of bondings, and m represents an integer of 0 to 4.]
Examples of the diamine represented by the chemical formula (13) include 1,3-bis(4-aminophenoxy)benzene, 1,4-bis(4-aminophenoxy)benzene, 1,3-bis(3-aminophenoxy)benzene, 4,4′-bis(3-aminophenoxy)biphenyl, 4,4′-bis(4-aminophenoxy)biphenyl, 3,3′-diaminobenzophenone, bis[4-(3-aminophenoxy)phenyl]ketone, bis[4-(4-aminophenoxy)phenyl]ketone, bis[4-(3-aminophenoxy)phenyl]sulfide, and bis[4-(4-aminophenoxy)phenyl]sulfide, bis[4-(3-aminophenoxy)phenyl]sulfone, bis[4-(4-aminophenoxy)phenyl]sulfone, bis[4-(3-aminophenoxy)phenyl]ether, bis[4-(4-aminophenoxy)phenyl]ether, 2,2-bis[4-(4-aminophenoxy)phenyl]propane, 2,2-bis[4-(3-aminophenoxy)phenyl]propane, bis(4-aminophenyl)terephthalate, bis(4-aminophenyl)biphenyl-4,4′-dicarboxylate, [4-(4-aminobenzoyl)oxyphenyl]4-aminobenzoate, and the like. The diamine component may be used alone or in combination of two or more types.

The fusion-bondable polyimide constituting the fusion-bondable polyimide layer is preferably non-crystalline from the viewpoint of improving the peel strength between the fusion-bondable polyimide layer and the heat-resistant polyimide layer, and between the fusion-bondable polyimide laver and the copper foil. The fusion-bondable polyimide being non-crystalline means that it has a glass transition temperature but no melting point is observed. To produce a fusion-bondable polyimide layer composed of a non-crystalline fusion-bondable polyimide, for example, such means as using a compound having an ether bond as a tetracarboxylic acid component or a diamine component may be employed.

From the viewpoint of improving the heat resistance of the resulting fusion-bondable polyimide film, the glass transition temperature of the fusion-bondable polyimide constituting the fusion-bondable polyimide layer is preferably 250° C. to 320° C., more preferably 270° C. to 300° C. The method for measuring the glass transition temperature will be described in detail in the examples described later.

### «Polyimide Metal Laminate»

The polyimide precursor composition or polyimide film of the present invention can be used to produce a polyimide metal laminate in which a polyimide film (or layer) and a metal foil (or layer) are laminated together. Examples of the method for producing a polyimide metal laminate include the following methods.
(i) A method of laminating a polyimide film and a substrate (e.g., a metal foil) directly or via an adhesive by applying pressure or applying heat and pressure;
(ii) A method of directly forming a metal layer on a polyimide film by a dry method (metallizing such as vacuum deposition and sputtering) and/or a wet method (plating);
(iii) A method of applying a polyimide precursor composition onto a substrate such as a metal foil, and drying and imidizing thereof.

In the above (i), when the polyimide film is directly laminated to a substrate (e.g., a metal foil), a multilayer polyimide film having a fusion-bondable layer on the surface, such as a two-layer structure of fusion-bondable PI layer/heat-resistant PI layer or a three-layer structure of fusion-bondable PI layer/heat-resistant PI layer/fusion-bondable PI layer, is preferably used.

In the above (i), when the polyimide film and the substrate (e.g., metal foil) are laminated via an adhesive, the adhesive is not particularly limited as long as it is a heat-resistant adhesive used in the electronics field, and examples thereof include polyimide-based adhesives, epoxy-modified polyimide-based adhesives, phenolic resin-modified epoxy resin adhesives, epoxy-modified acrylic resin adhesives, epoxy-modified polyamide-based adhesives, and the like. The heat-resistant adhesive layer can be provided by any method that is itself used in the electronics field, and for example, the above-mentioned polyimide film or a formed product may be coated with an adhesive solution and dried, or a separately formed film-like adhesive may be laminated.

In the above (i) and (iii), examples of the substrate include an elemental metal or an alloy, such as a metal foil of copper, aluminum, gold, silver, nickel, or stainless steel, and a metal plating layer (preferably a vapor-deposited metal underlayer-metal plating layer or a chemical metal plating layer, or other known techniques can be applied), and preferred examples include rolled copper foil, electrolytic copper foil, copper plating layer, and the like. The thickness of the metal foil is not particularly limited, but is preferably 0.1 μm to 10 mm, more preferably 1 to 50 μm, and particularly preferably 5 to 18 μm.

As the dry method (metallizing method) used in the above (ii), known methods such as vacuum deposition, sputtering, ion plating, and electron beam can be used. As the metal used in the metallizing method, metals such as copper, nickel, chromium, manganese, aluminum, iron, molybdenum, cobalt, tungsten, vanadium, titanium, tantalum, and the like, or alloys thereof, or oxides of these metals, carbides of these metals, and the like can be used, but are not particularly limited to these materials. The thickness of the metal layer formed is, for example, 1 nm to 500 nm, and a metal plating layer of copper, tin, or the like can be provided on this surface to a thickness of, for example, 1 μm to 40 μm by a known wet plating method such as electrolytic plating or electroless plating.

As the wet method (plating method) used in the above (ii), a known plating method can be used, and examples of the plating method include electrolytic plating and electroless plating, and these methods may be employed in combination. There is no limitation on the metal used in the wet plating method as long as it can be wet-plated.

The thickness of the metal layer formed by the wet plating method can be appropriately selected depending on the purpose of use, and is preferably in the range of 0.1 to 50 μm, more preferably 1 to 30 μm for practical use. The number of layers of the metal layer formed by the wet plating method can be appropriately selected depending on the purpose of use, and may be one layer, two layers, or multiple layers of three or more layers.

Examples of the wet plating method include the conventionally known Elfseed Process available from Ebara-Udylite Co., Ltd. and the Catalyst Bond Process, which is a surface treatment process available from JX Nippon Mining & Metals Co., Ltd., followed by electroless copper plating.

Since the polyimide film of the present invention has a small dielectric loss tangent in the high frequency range and at the same time has excellent alkali resistance, the polyimide metal laminate of the present invention (including both a laminate in which a film and a metal layer are laminated via an adhesive layer and a laminate in which a metal layer is formed directly on a film) can be suitably used for flexible wiring board applications. That is, a flexible wiring board can be produced by patterning the metal foil (or metal layer) of the polyimide metal laminate by a known method to form wiring.

The polyimide precursor composition, polyimide film or polyimide metal laminate of the present invention can be used not only for flexible wiring boards, but also for TAB tapes, COF tapes, flexible heaters, resistor substrates, insulating films, protective films, and the like.

### EXAMPLES

The present invention will now be described in more detail with reference to examples and comparative examples.

The following abbreviations are used hereinafter:

### <Tetracarboxylic Acids>

s-BPDA: 3,3′,4′-biphenyltetracarboxylic dianhydride
PMDA: Pyromellitic dianhydride
ODPA: Oxydiphthalic dianhydride (also known as bis(3,4-dicarboxyphenyl)ether dianhydride)

### <Diamines>

PPD: p-phenylenediamine
m-TB: 2,2′-dimethyl-4,4′-diaminobiphenyl (also known as m-tolidine)
BPTP: bis(4-aminophenyl)terephthalate
BAPP: 2,2-bis[4-(4-aminophenoxy)phenyl]propane

### <Others>

DMAc: N,N-dimethylacetamide

Table 1 shows structural formulas of tetracarboxylic acid component and diamine component.

TABLE 1

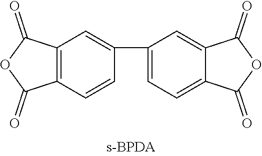 [SMILES: O=C1OC(=O)c2cc(-c3ccc4c(c3)C(=O)OC4=O)ccc21]

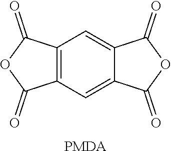

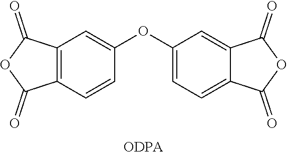

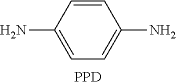

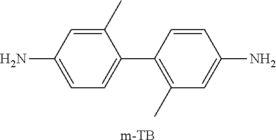

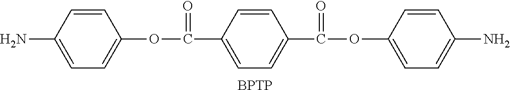

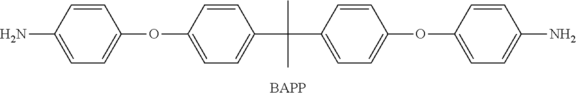

### <Evaluation of Polyimide Film>

### [Storage Modulus]

The dynamic viscoelasticity of the polyimide film was measured using a TA Instruments RSA G2 dynamic viscoelasticity measuring device at a temperature rise rate of 10° C./min and a frequency of 1 Hz, and the 35° C. storage modulus and 350° C. storage modulus were determined from a plot of storage modulus against temperature.

### [Dielectric Loss Tangent]

A split cylinder resonator 10 GHz CR-710 (manufactured by EM Lab) was used as the measuring device, and the dielectric loss tangent of the polyimide film was measured under the following conditions.
Measurement frequency: 10 GHz
Measurement conditions: temperature 25±2° C., humidity 60±2% RH
Measurement sample: A sample that had been left to stand for 48 hours under the above measurement conditions was used.

### [Alkali Resistance Test, MIT Folding Endurance Test]

A test piece for the MIT folding endurance test having a width of 15 mm (over the entire width) was cut out. A 10 wt % aqueous solution of sodium hydroxide was prepared as an alkaline solution, and the test piece for the MIT folding endurance test was immersed in the solution at 50° C. for 6 hours, then ultrasonically washed with water for 1 hour, and then dried.

For the sample immersed in the alkaline solution, the number of times until the polyimide film broke was measured according to ASTM D2176 under the conditions of a curvature radius of 0.38 mm, a load of 9.8 N, a bending speed of 175 times/min, and a left-right bending angle of 135 degrees. The measured number of times was used as an index of alkali resistance.

### Example 1

### [Preparation of Polyimide Precursor Composition]

To a reaction vessel equipped with a stirrer and a nitrogen inlet tube, DMAc was added and then PDP and BPTP were added as diamine components. Next, s-BPDA and ODPA were added as a tetracarboxylic acid dianhydride component in an equimolar amount to the diamine components and reacted to obtain a polyimide precursor composition with a monomer concentration of 18% by mass and a solution viscosity of 1800 poise at 30° C. The molar ratio of PPD to BPTP was 50:50, and the molar ratio of s-BPDA to ODPA was 80:20.

### [Method for Manufacturing Polyimide Film]

The polyimide precursor composition was cast on a glass plate in a thin film form, heated in an oven at 120° C. for 12 minutes, and peeled off from the glass plate to obtain a self-supporting film. The four sides of the self-supporting film were fixed with pin tenters, and gradually heated in a heating furnace from 150° C. to 450° C. (maximum heating temperature was 450° C.) to remove the solvent and imidize the film to obtain a polyimide film.

The thickness of the polyimide film was about 25 μm, and it was used for measuring the dielectric loss tangent and the storage modulus. For the alkali resistance test, a thick polyimide film was separately produced. The evaluation results are shown in Table 2.

### Examples 2 to 5, Comparative Examples 1 to 7

A polyimide precursor composition was prepared in the same manner as in Example 1, except that the tetracarboxylic acid component and the diamine component were changed to the compounds and amounts (molar ratios) shown in Table 2. Thereafter, a polyimide film was produced in the same manner as in Example 1, and the physical properties of the film were evaluated. The evaluation results are shown in Table 2.

TABLE 2

| | | | | | | | | Film | | | |
|---|---|---|---|---|---|---|---|---|---|---|---|
| | | | | | | | | thickness | MIT | | |
| | | | | | | | Dielectric | (after | (after | Storage modulus | |
| | Acid dianhydride | | | Diamine | | | loss | treatment) | treatment) | (GPa) | |
| | s-BPDA | PMDA | ODPA | PPD | m-TB | BPTP | tangent | (μm) | (times) | 35° C. | 350° C. |
| Comp-Ex 1 | 80 | | 20 | 100 | | | 0.0059 | 65 | 182 | 8.02 | 0.54 |
| Comp-Ex 2 | 80 | | 20 | 80 | | 20 | 0.0036 | 45 | 2,222 | 8.03 | 0.33 |
| Comp-Ex 3 | 80 | | 20 | 60 | | 40 | 0.0032 | 46 | 784 | 7.56 | 0.21 |
| Example 1 | 80 | | 20 | 50 | | 50 | 0.0028 | 50 | 19,911 | 8.13 | 0.47 |
| Example 2 | 80 | | 20 | 40 | | 60 | 0.0032 | 44 | 13,640 | 7.13 | 0.35 |
| Example 3 | 80 | | 20 | | | 100 | 0.0032 | 42 | 16,886 | 6.38 | 1.35 |
| Comp-Ex 4 | 80 | 20 | | 100 | | | 0.0075 | 42 | 1,556 | 8.01 | 0.62 |
| Comp-Ex 5 | 80 | 20 | | 80 | | 20 | 0.0045 | 38 | 191 | 7.42 | 0.4 |
| Example 4 | 80 | 20 | | 50 | | 50 | 0.0036 | 41 | 5,193 | 7.86 | 0.31 |
| Example 5 | 80 | 20 | | | | 100 | 0.0036 | 39 | 7,666 | 6.83 | 0.85 |
| Comp-Ex 6 | 80 | | 20 | 50 | 50 | | 0.0051 | 47 | 1,224 | 6.81 | 0.06 |
| Comp-Ex 7 | 100 | | | | | 100 | 0.0043 | | | 7.17 | 1.45 |

Comp-Ex = Comparative Example

Compared to the corresponding comparative examples, the working examples have larger MIT number of folding endurance times after alkaline solution treatment, indicating that the alkali resistance has been improved. Comparative Example 6, which did not contain BPTP, was inferior in alkali resistance and had a large dielectric loss tangent. Comparative Example 7, which did not contain PMDA and/or ODPA, had a large 350° C. elastic modulus. Examples 1 and 2, and Example 4, have improved 350° C. elastic modulus compared to Examples 3 and 5, respectively, indicating that they were more preferable compositions.

### <Multilayer Polyimide Film>

A multilayer polyimide film having a three-layer structure of fusion-bondable PI layer/heat-resistant PI layer/fusion-bondable PI layer was produced, in which the polyimide film of the present invention was used as the heat-resistant PI layer (core layer). The polyimide precursor composition for producing the core layer was prepared in the same manner as in Example 1, except that the tetracarboxylic acid component and the diamine component in Example 1 were changed to the compounds and amounts (molar ratios) shown in Table 3.

### [Preparation of Polyimide Precursor Composition Giving Fusion-Bondable Polyimide]

To a reaction vessel equipped with a stirrer and a nitrogen inlet tube, DMAc was added and then BAPP was added as a diamine component. Next, s-BPDA and PMDA were added as tetracarboxylic acid dianhydride components in an equimolar amount to the diamine components and reacted to obtain a polyimide precursor composition with a monomer concentration of 18% by mass and a solution viscosity of 800 poise at 30° C. The molar ratio of s-BPDA to PMDA was 30:70.

### [Method for Manufacturing Polyimide Film]

From a three-layer extrusion die, the polyimide precursor composition for producing the core layer and the polyimide precursor composition for forming the fusion-bondable layer were extruded and cast onto the upper surface of a smooth metal support into a thin film so as to have structure of fusion-bondable PT layer/heat-resistant PI layer/fusion-bondable PI layer. The thin-film cast product was continuously dried with hot air at 140° C. to form a self-supporting film. After peeling the self-supporting film from the support, it was gradually heated from 200° C. to 3900° C. (maximum heating temperature was 390° C.) in a heating furnace to remove the solvent and imidize the film to produce a multilayer polyimide film with a three-layer structure having a thickness of 50 μm (5.7 μm/38.6 μm/5.7 μm).

The results of the dielectric loss tangent measurement and the MIT folding endurance test after alkaline solution treatment of the produced multi-layer polyimide film are shown in Table 3.

TABLE 3

| | | | | | | | | | MIT |
|---|---|---|---|---|---|---|---|---|---|
| | Core layer | | | | Fusion-bondable layer | | | Dielectric | (after |
| | Acid dianhydride | | Diamine | | Acid dianhydride | | Diamine | loss | treatment) |
| | s-BPDA | ODPA | PPD | BPTP | s-BPDA | PMDA | BAPP | tangent | (times) |
| Comp-Ex M1 | 100 | | 100 | | 30 | 70 | 100 | 0.0085 | 2,552 |
| Comp-Ex M2 | 80 | 20 | 80 | 20 | 30 | 70 | 100 | 0.0045 | 1,261 |
| Example M1 | 80 | 20 | 50 | 50 | 30 | 70 | 100 | 0.0040 | 3,539 |

Also in the case that the polyimide film having the composition of the present invention is used as a heat-resistant PI layer (core layer), these results show that the multi-layer polyimide film has a small dielectric loss tangent and excellent alkali resistance, and thus it is ideal for producing flexible copper-clad laminates.

### INDUSTRIAL APPLICABILITY

A polyimide film produced from the polyimide precursor composition of the present invention can be suitably used for flexible wiring, board applications.

What is claimed is:

1. A polyimide precursor composition for flexible wiring boards, comprising a polyimide precursor having a repeating unit represented by the following general formula (I): 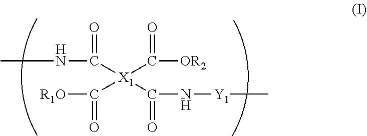
wherein in general formula I, X₁ is a tetravalent aliphatic group or aromatic group, Y₁ is a divalent aliphatic group or aromatic group, R₁ and R₂ are each independently a hydrogen atom, an alkyl group having 1 to 6 carbon atoms or an alkylsilyl group having 3 to 9 carbon atoms,
wherein 70 mol % to 90 mol % of X₁ is a group represented by following formula (21), and 10 to 30 mol % is a group represented by following formula (22) and/or a group represented by following formula (23), 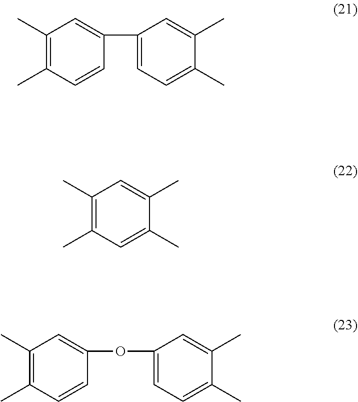
and
45 mol % to 100 mol % of Y₁ is a group represented by formula (1): 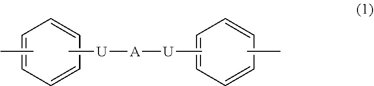
wherein in formula (1), A is a structure represented by formula (A): 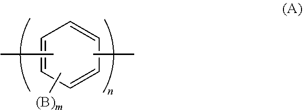
wherein n is an integer of 1 to 4, m is an integer of 0 to 4, B is selected from the group consisting of an alkyl group having 1 to 6 carbon atoms, an alkoxy group having 1 to 6 carbon atoms, a halogen group, and a fluoroalkyl group having 1 to 6 carbon atoms, and U independently represents —CO—O— or —O—CO—.

2. The polyimide precursor composition according to claim 1, wherein A is a structure selected from the group consisting of a 1,4-phenylene group and a 4,4′-biphenylene group.

3. A polyimide film for flexible wiring boards, obtained from the polyimide precursor composition according to claim 1.

4. A polyimide metal laminate comprising a polyimide film according to claim 3 and a metal foil or metal layer laminated therewith.

5. A flexible wiring board having wiring formed by patterning the metal foil or metal layer of the polyimide metal laminate according to claim 4.
